(19) United States
(12) Patent Application Publication
(10) Pub. No.: US 2026/0208609 A1
(43) Pub. Date: Jul. 23, 2026

(54) BATTERY CHARGING COMPLEX FOR ELECTRIC VEHICLE FLEET

(71) Applicant: DRIVE ELECTRO SA, Lausanne (CH)

(72) Inventor: Sergey IVANOV, Kava Tivat (ME)

(21) Appl. No.: 19/141,252

(22) PCT Filed: Sep. 28, 2023
(86) PCT No.: PCT/IB2023/059667

§ 371 Date: Jun. 19, 2025

(51) Int. Cl. B60L 53/53; B60L 53/67; G01R 31/382

(52) U.S. Cl. CPC B60L 53/53; B60L 53/67; G01R 31/382

(57) ABSTRACT

The invention relates to complexes for charging groups of electric vehicles used for urban needs, and can be used in the transportation industry and by municipal enterprises. The purpose of the invention consists in the battery charging complex for electric vehicles fleet, including: the group of the same type electric vehicles and the group of charging stations containing buffer batteries, wherein traction batteries and buffer batteries are of the same type, and buffer batteries are represented by formerly used traction batteries and have a storage capacity ranging from 60 to 80% of the nominal one. The invention is aimed to achieve the technical result, that is to increase the useful life of traction accumulator batteries of electric vehicles by continuing their operation as buffer batteries of charging stations of the complex for charging batteries of the electric vehicles fleet. 3 sub-claims, 2 figures.

The invention relates to complexes for charging groups of electric vehicles used for urban needs, and can be used in the transportation industry and by municipal enterprises.

A system for charging batteries of an electric vehicles fleet is known, comprising: an electric bus comprising traction batteries, a traction motor and a device for connection to a charging station and a charging station [US2022407349A1, publication date: Dec. 22, 2022].

The disadvantage of the prior art is the absence of prerequisites and technical means for tracking the deterioration of the characteristics of traction batteries used to drive the traction motor of an electric bus, and their timely utilization or re-profiling to extend their useful life.

The complex for optimizing the use of batteries of the electric vehicles fleet is selected as a prototype, including: a group of similar electric vehicles containing traction batteries, equipped with a condition monitoring system, traction motors and devices for connection to the charging station, while the monitoring system is configured to dynamically or periodically record data on traction batteries, including tracking their current and initial state of charging and discharging temperature, declared or expected calendar life, voltage, energy density, depth of discharge, and other data, on the basis of which the approximate life or end of life of traction batteries is determined and recommendations for repurposing or selling the traction battery for recycling or disposal are formed [WO2020036984A 1, publication date: Feb. 20, 2020].

Advantageously, the prototype is capable of providing a recommendation for repurposing or selling the traction battery for reuse based on data obtained from the traction battery monitoring system.

However, a common disadvantage of the prototype and the prior art is the lack of specific tools providing the possibility of effective reuse of traction batteries unsuitable for driving the traction motor of an electric vehicle and not yet completely out of service.

Current technologies only offer the possibility to recycle them, but the widespread use of electric vehicles results in huge volumes of battery waste that the world's infrastructure may not be able to cope with, since the known technologies for the disposal and recycling of traction batteries are not yet perfect, problematic and highly costly. This stems from the fact that battery packs must be disassembled to at least the module level to improve the efficiency of recovery and recycling processes. However, the hazards associated with disassembling traction batteries are numerous.

Disassembly of traction batteries requires training in high voltage operation to prevent electric shock or short-circuiting of the battery. A short circuit results in a rapid discharge that can cause heating and thermal runaway. The latter can lead to the formation of particularly harmful by-products, including gaseous hydrogen fluoride, which together with other gaseous products can cause the elements to explode. Battery cells present chemical hazards due to flammable electrolytes, toxic and carcinogenic electrolyte additives, and potentially toxic or carcinogenic electrode materials. Pyrometallurgical and hydrometallurgical technologies have been developed to improve the efficiency of traction battery recycling, but they are disadvantageous because of high capital costs and low quality of recovered metals. Thus, alternative methods are urgently required if the full suitability of end-of-life traction batteries as a source of secondary raw materials is to be ensured.

In contrast to the utilization of traction batteries there is the technology of their re-profiling, but at this stage it is underdeveloped and can not offer a specific and simple solution for the reuse of traction batteries in existing industries.

In view of the existing drawbacks, there is a need to develop a demanded and effective technical solution in terms of reusing traction batteries of electric vehicles before their complete failure and thus improving the performance of the existing solution in the field of optimizing the use of batteries.

The invention is intended to solve the technical problem, which lies in the need to improve the performance characteristics of the complex for optimizing the use of batteries of the electric vehicles fleet.

The invention is aimed to achieve the technical result, that is to increase the useful life of traction accumulator batteries of electric vehicles by continuing their operation as buffer batteries of charging stations of the complex for charging batteries of the electric vehicles fleet.

The purpose of the invention is as follows.

The battery charging complex for electric vehicles fleet includes: the group of similar electric vehicles containing traction batteries equipped with the system for condition monitoring, traction motors and devices for connecting them to the charging station. In contrast to the prototype, the complex additionally contains a group of charging stations containing buffer batteries equipped with a system for monitoring their condition, wherein traction accumulator batteries of electric vehicles and buffer accumulator batteries of charging stations are of the same type, and buffer accumulator batteries of charging stations are represented by used traction accumulator batteries of electric vehicles of the mentioned electric vehicles fleet and have storage capacity from 60 to 80% of the nominal one.

The battery charging complex for electric vehicles flee provides the possibility of replenishing the energy of land vehicles, predominantly used for urban or municipal purposes. By a group of similar electric vehicles within the scope of the present invention is meant a fleet of electric buses or trolleybuses with extended autonomous travel, or electric cargo vehicles equipped with traction batteries and driven by traction motors and other similar vehicles, including passenger cars used as cabs or for rental purposes as well as autonomous vehicles without a driver. Also, the group of similar electric vehicles may include specialized vehicles or utility vehicles, which may be represented by cleaning, repairing and other vehicles of similar purpose. To receive electrical energy from the charging station, the electric vehicle contains a device for connecting to the charging station represented by a current collector or electrical connector of any known type, such as CCS2, CHAdeMO or wireless electrical energy transmission devices, etc.

The group of charging stations within the scope of the present invention refers to elements of urban infrastructure that provide electricity for charging electric vehicles. Each charging station includes at least one of the following connected in series: an input for connection to an AC power source, a surge protector, a circuit breaker, a contactor switching the input AC current, a power unit converting AC to DC current, a buffer battery for storing electrical energy, a power unit converting DC current of one magnitude to DC current of another magnitude, a contactor switching the output DC current, a charging connector, a charging dome or charging platform, a user interface, and a controller to which the following is connected: power units, buffer battery, and contactors switching the input AC and output DC currents.

The AC input provides a means of obtaining electrical power from the general purpose grid and may be represented by a feeder or other devices for connection to a high-voltage electrical circuit. The surge protection device protects the station components against short-term voltage rises and impulses caused by lightning discharges, works in the electric grid, switching in the power supply system, etc. This device can be represented as a varistor limiter, arrester, etc. The circuit breaker protects the electrical circuit against overload and short-circuit currents. The circuit breaker can be represented by a mechanical or electronic switching device.

The contactor switching the input AC is designed for emergency disconnection from the AC electric grid. The power unit that converts AC to DC may be represented by an inverter, rectifier, or other devices that provide a similar function.

The buffer battery reduces DC voltage fluctuations in the circuit and also provides for electrical energy storage, allowing for shorter charge times for the electric vehicle. The power unit, which provides the conversion of DC of one magnitude to DC of another magnitude, allows control of the characteristics of the output charging current. The contactor switching the output DC is designed to disconnect the charging connector from the buffer battery and interrupt the charging process of the electric vehicle. The contactors present in the charging station may be represented by electromagnetic devices and other devices.

The controller provides the possibility of controlling the charging process and for this purpose is connected to the contactor switching the input AC and a contactor switching the output DC with the possibility of transmitting control signals. The controller is also configured to change the characteristics of the DC current converted by the power unit, which allows a smooth adjustment of the charging process, which also reduces the risk of failure of the components of the charging station for electric vehicles. Also connected to the controller are: the power unit converting AC into DC, contactors switching input AC and output DC, which provides the possibility of sending them signals to control the charging process. The buffer battery is also connected to the controller to allow monitoring of its status. Connection of the controller to the above-mentioned elements may be provided by means of wires, busbars or cables. The user interface may be represented by data input/output devices connected to the controller.

Additionally, the charging station may comprise the controller for communicating with the electric vehicle to be charged via the charging connector.

The charging station can be mounted in an enclosure, cabinet or board that provides the supporting and protective functions of the charging station. The charging station elements may be secured by any known type of detachable or non-detachable connection.

Traction batteries of electric vehicles and buffer batteries of charging stations belong to the same type, which ensures their complete interchangeability and the possibility of utilizing used traction batteries of electric vehicles as buffer batteries of charging stations without the need to change the charging station design. This approach allows increasing the useful life of traction batteries of electric vehicles within the complex for charging batteries of electric vehicle fleets due to their timely utilization as buffer batteries of charging stations. Lithium-titanate (LTO), niobium-titanate (NTO), lithium-manganese (NMC), lithium ferrophosphate (LFP) and other types of batteries can be presented as traction and buffer batteries.

As buffer batteries of charging stations, previously used traction batteries of electric vehicles with storage capacities ranging from 60 to 80% of the nominal capacity are presented. This approach to the use of traction batteries reduces the risk of possible immobilization of the electric vehicle and ensures sufficient life of the traction battery for its use as the buffer battery. Storage capacity is the amount of electricity given up by the battery as it discharges until it reaches its final voltage. During the first charge-discharge cycles, the storage capacity increases as the active mass of the plates is developed. During operation, the capacity remains stable for some time and then begins to gradually decrease due to aging of the active mass of the plates.

If the storage capacity of the traction battery is more than 80% of the rated capacity, it may be used effectively and safely to drive the traction motor of the electric vehicle without risk of immobilization due to failure of the traction battery. If the storage capacity of the traction battery is less than 60% of the rated capacity, it is considered to be out of service and is not suitable for use as the buffer battery because the required capacity is not provided and energy storage takes a long time or does not occur at all.

The invention may be made from known materials using known tools, which evidences its compliance with the patentability criterion of “industrial feasibility”.

The invention is characterized by a set of essential features previously unknown in the art, characterized in that the complex for charging electric vehicles additionally contains the group of charging stations containing buffer accumulator batteries equipped with the system for condition monitoring, wherein traction accumulator batteries of electric vehicles and buffer accumulator batteries of charging stations are of the same type, and buffer accumulator batteries of charging stations are represented by used traction accumulator batteries of electric vehicles of the mentioned electric vehicles fleet and have storage capacity from 60 to 80% of the nominal one. This makes it possible to continue the operation of traction batteries, which are not suitable for powering traction motors of electric vehicles, as buffer batteries of charging stations intended for accumulation of electric current and its use in charging electric vehicles until the complete failure of such battery.

Due to this the technical result is achieved, consisting in increase of useful life of traction batteries of electric vehicles at the expense of continuation of their operation as buffer batteries of charging stations of the complex for charging batteries of the electric vehicles fleet, thus improving operational characteristics of the complex for optimization of use of batteries of the electric vehicles fleet.

The inventions has a set of essential features unknown in the prior art, which indicates its compliance with the patentability criterion of “novelty”.

The distinctive features of the invention are unknown in the prior art, in view of which the invention meets the patentability criterion of “inventive level”.

The invention is explained by the following figures.

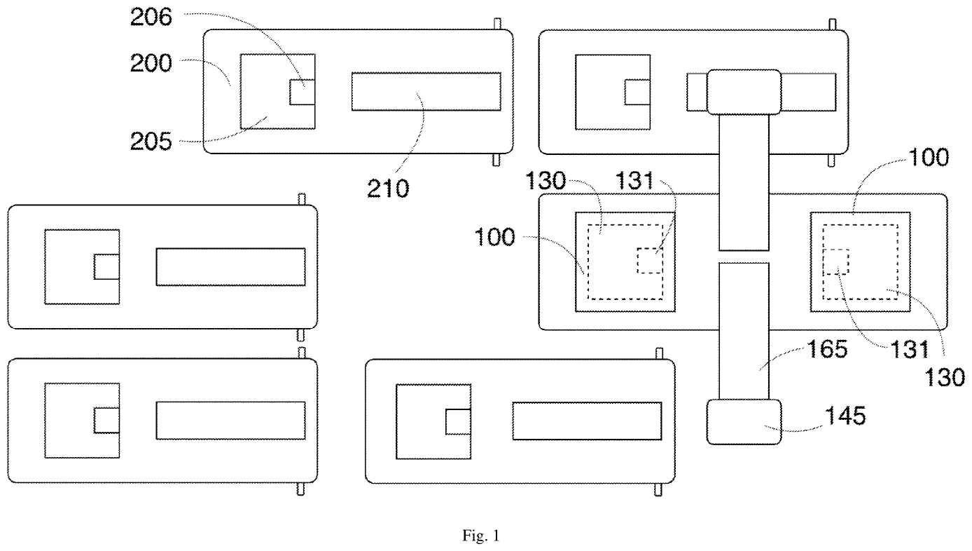

FIG. 1 is the functional diagram of the complex for charging the batteries of the electric vehicles fleet, top view.

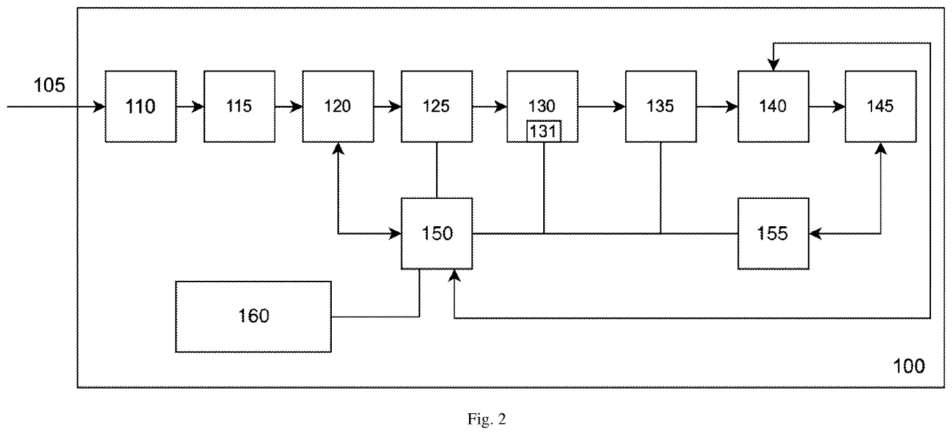

FIG. 2 is the functional diagram of the charging station for electric vehicles.

An embodiment, which may be amended or supplemented in any way, is given below to demonstrate the feasibility and better understanding of the essence of the invention, whereby the present invention is by no means limited by the embodiment presented.

The battery charging complex for electric vehicles flee includes: the group of charging stations (CS) 100 for electric vehicles and the group of municipal electric vehicles (EV) 200 represented by electric buses.

Each charging station 100 contains connected in series: inlet 105 for connection to the AC source, surge protection device 110, circuit breaker 115, contactors 120 switching the input AC current, power unit 125 converting AC current to DC current, buffer battery (BAT) 130 for storing electrical energy, provided with system 131 for monitoring its condition, represented by sensors for monitoring temperature and electrical characteristics, as well as the temperature control system, power unit 135, converting DC of one magnitude into DC of another magnitude, contactors 140, switching the output DC, and charging dome 145 for connection to EV.

The charging station also includes controller 150 controlling contactors 120 and 140, to which the following is connected by the data bus: power unit 125, buffer battery condition monitoring system 131, power unit 135, and controller 155 providing communication with EV to be charged. User interface 160, represented as the display and control panel, is connected to controller 150. Charging dome 145 is externally secured to boom 165.

Each EV 200 is represented as the electric bus containing roof-mounted: traction accumulator battery (BAT) 205 provided with system 206 for condition monitoring, represented by the control unit and sensors for monitoring temperature and electrical characteristics of the battery and the system for battery temperature control. Meanwhile, each EV 200 includes current collector 210.

The buffer and traction batteries 130 and 205 are lithium-titanate (LTO) batteries and have a nominal storage capacity of 80 kW*/hr, with buffer battery 130 represented by used traction battery 205, which has a capacity of 60-80% of its nominal capacity.

The invention operates as follows.

In the “idle” mode, the charging station provides charging of buffer battery 130, and when battery 130 reaches full charge, the charging station enters the standby mode.

When current collector 210 of the electric vehicle is connected to charging dome 145, the charging station functionality is diagnosed by controller 150. When the electric vehicle is placed for charging, communication with electric vehicle 200 to be charged is established via controllers 150 and 155 and charging dome 145, the contactors 140 are closed, and a precharge is performed during which voltages between traction battery 205 and charging station 100 are equalized. Charging station 100 is then put into a charging mode by controller 150, whereby it calculates the maximum electric current power that can be provided by charging station 100. It is calculated by controller 150 depending on the charge level and parameters of buffer battery 130. If the charge level of buffer battery 130 is more than 20%, the power of electric current supplied to charging dome 145 is calculated based on the parameters of buffer battery 130. If the charge level of buffer battery 130 is below 20%, the power is limited to the value of maximum allowable power that can be obtained from the electric grid.

In the course of operation of EV 200 groups, there is a gradual decrease in energy intensity of their traction batteries 205 to a value of 80%, which is recorded by system 206 monitoring its condition. When the specified storage capacity value is reached, traction battery 205 is unable to effectively perform its functions of driving the traction motor of EV 200 and there is a significant decrease in the possible distance covered by EV 200, the payload of EV 200 is reduced and the risk of failure of battery 205 increases, which may lead to immobilization of EV 200. For this reason, traction battery 205 with reduced storage capacity is removed and installed in the circuit of charging station 100 in place of failed buffer battery 130.

In view of the fact that the presented storage capacity of battery 205 is sufficient to provide the functions of buffer battery 130, which consist in reducing the load on the electric grid during express charging of EV 200, it is used until it fails completely, in particular until its storage capacity drops below 60%, after which battery 205 used as buffer battery 130 is disposed of and its replacement cycle is repeated.

In this way, it is ensured that traction batteries 205, which are not suitable for powering the traction motors of electric vehicles 200, can continue to be used as buffer batteries 130 of the charging stations to store electric current and use it in charging electric vehicles 200 until the complete failure of such battery.

Thus, the technical result is achieved, consisting in increase of useful life of traction batteries of electric vehicles at the expense of continuation of their operation as buffer batteries of charging stations of the complex for charging batteries of the electric vehicles fleet, thus improving operational characteristics of the complex for optimization of use of batteries of the electric vehicles fleet.

1. The battery charging complex for electric vehicles fleet, including: the group of similar electric vehicles (200) containing traction batteries (205) equipped with the system (206) for condition monitoring, traction motors and devices for their connection to the charging station (100), characterized in that additionally contains the group of charging stations including buffer batteries (130) equipped with the system (131) for condition monitoring, wherein traction accumulator batteries (205) of electric vehicles (200) and buffer accumulator batteries (130) of charging stations (100) are lithium-titanate batteries or niobium-titanate batteries, and buffer accumulator batteries (130) of charging stations (100) are represented by used traction accumulator batteries (205) of electric vehicles (200) of the mentioned electric vehicles fleet and have storage capacity from 60 to 80% of the nominal one.

2. The complex according to claim 1, characterized in that the battery condition monitoring system (131, 206) is represented by the control unit and sensors for monitoring the temperature and electrical characteristics of the battery (130, 205).

3. The complex according to claim 1, characterized in that the group of similar electric vehicles (200) is represented by specialized vehicles or utility vehicles, as well as electric buses or trolleybuses with increased autonomous travel or electric cargo vehicles equipped with traction batteries (205) and driven by traction electric motors, as well as autonomous vehicles without a driver.
